(19) United States
(12) Patent Application Publication
(10) Pub. No.: US 2026/0074688 A1
(43) Pub. Date: Mar. 12, 2026

(54) GATE DRIVE APPARATUS, POWER CONVERSION APPARATUS, AND INVERTER

(71) Applicant: KABUSHIKI KAISHA TOSHIBA, Tokyo (JP)

(72) Inventor: Koutaro MIYAZAKI, Tokyo (JP)

(73) Assignee: KABUSHIKI KAISHA TOSHIBA, Tokyo (JP)

(21) Appl. No.: 19/280,289

(22) Filed: Jul. 25, 2025

(30) Foreign Application Priority Data
Sep. 11, 2024 (JP) 2024-157843

(51) Int. Cl. H03K 17/16; H02M 1/00; H02M 1/084; H02M 7/5395; H03K 17/0812; H03K 17/14

(52) U.S. Cl. CPC H03K 17/16; H02M 1/0054; H02M 1/0845; H02M 7/5395; H03K 17/0812; H03K 17/14

(57) ABSTRACT

According to one embodiment, a gate drive apparatus includes a loss calculation circuit configured to estimate a loss value of a power device by using voltage values at a plurality of time points of the power device. The loss calculation circuit includes an integration circuit configured to perform time integration based on the voltage values at the plurality of time points. The loss calculation circuit also includes an estimation circuit configured to estimate the loss value of the power device based on a result of the time integration.

### CROSS REFERENCE TO RELATED APPLICATION

This application is based upon and claims the benefit of priority from the prior Japanese Patent Application No. 2024-157843, filed on Sep. 11, 2024, the entire contents of which are incorporated herein by reference.

### FIELD

Embodiments of the present invention relate to a gate drive apparatus, a power conversion apparatus, and an inverter.

### BACKGROUND

Power devices suffer from losses or short circuits associated with degradation and the like. It has been a practice to estimate a loss in a power device. In a case in which a loss in the power device is estimated to be large, a Fault signal is transmitted to a controller side, and the controller protects the power device based on this signal.

### BRIEF DESCRIPTION OF THE DRAWINGS

FIG. 1 is a schematic configuration diagram of a power conversion apparatus in a first embodiment;

FIG. 2 is an example of a circuit diagram of an inverter in the first embodiment;

FIG. 3 is a diagram illustrating configurations of a loss calculation circuit and a power device in the first embodiment;

FIG. 4 is a diagram illustrating a relation between a drain-source voltage “V_{CE}” of the power device and a drain current that flows at this voltage;

FIG. 5A and FIG. 5B are diagrams illustrating a comparative image of an estimation value of a loss in the first embodiment and an estimation value of a loss in a comparative example;

FIG. 6 is a diagram for explaining another operation of the power device in the first embodiment;

FIG. 7 is a diagram illustrating configurations of a loss calculation circuit and a power device in a second embodiment;

FIG. 8 is a diagram illustrating configurations of a loss calculation circuit and a power device in a first modification of the second embodiment;

FIG. 9 is a diagram illustrating configurations of a loss calculation circuit and a power device in a second modification of the second embodiment;

FIG. 10 is a diagram illustrating configurations of a loss calculation circuit and a power device in a third modification of the second embodiment;

FIG. 11 is a diagram illustrating configurations of a loss calculation circuit and a power device in a fourth modification of the second embodiment;

FIG. 12 is a diagram illustrating a configuration of a current estimation circuit in a fifth modification of the second embodiment;

FIG. 13 is a diagram illustrating a configuration of a short-circuit determination circuit in a sixth modification of the second embodiment;

FIG. 14 is a diagram illustrating a configuration of a short-circuit determination circuit in a seventh modification of the second embodiment;

FIG. 15 is a diagram illustrating a configuration of a short-circuit determination circuit in an eighth modification of the second embodiment;

FIG. 16 is a diagram illustrating configurations of a loss calculation circuit and a power device in a ninth modification of the second embodiment;

FIG. 17 is a diagram illustrating configurations of a loss calculation circuit and a power device in a third embodiment;

FIG. 18 is a diagram illustrating configurations of a loss calculation circuit and a power device in a modification of the third embodiment;

FIG. 19 is a diagram illustrating configurations of a loss calculation circuit and a power device in a fourth embodiment; and

FIG. 20 is a diagram illustrating configurations of a loss calculation circuit and a power device in a modification of the fourth embodiment.

### DETAILED DESCRIPTION

Embodiments will now be explained with reference to the accompanying drawings. The present embodiments do not limit the present invention. The drawings are schematic or conceptual, and ratios and the like of respective portions are not necessarily the same as real ratios. Throughout the specification and the drawings, the same element as an element that has been previously described in relation to a drawing that has been previously described is denoted by the same reference numeral, and detailed description thereof will be appropriately omitted.

According to one embodiment, there is provided a loss calculation circuit configured to estimate a loss value of a power device using voltage values at a plurality of time points of the power device. The loss calculation circuit includes an integration circuit configured to perform time integration based on the voltage values at the plurality of time points. The loss calculation circuit includes an estimation circuit configured to multiply a result of the time integration by a predetermined proportional constant.

In the present disclosure, wording of “equal to or larger than” and “equal to or smaller than” can be also read as “larger than” and “smaller than”, respectively.

### First Embodiment

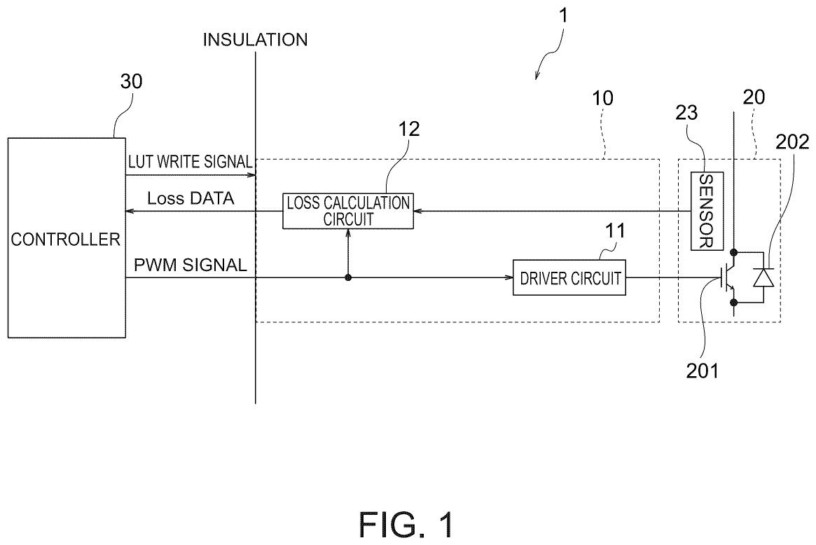

FIG. 1 is a schematic configuration diagram of a power conversion apparatus 1 in a first embodiment.

The power conversion apparatus 1 includes a gate drive apparatus 10, a power device 20, and a controller 30. The power conversion apparatus 1 outputs various signals by control of the controller 30, and causes the power device 20 to operate based on these signals. The power conversion apparatus 1 in the present embodiment estimates a loss value from an on-voltage of the power device 20. If it is determined that the loss value generated in the power device 20 is large, the apparatus is stopped or the like to protect the power device 20.

The gate drive apparatus 10 includes a driver circuit 11 and a loss calculation circuit 12. The driver circuit 11 is operated by a PWM signal supplied from the controller 30, and supplies a control voltage “Dr” to a gate of the power device 20 to be driven. In this way, the gate drive apparatus 10 controls operation of the power device 20. The loss calculation circuit 12 performs short-circuit determination for the power device 20, and estimates a loss generated in the circuit based on the on-voltage of the power device 20. A detailed configuration of the loss calculation circuit 12 will be described later. A result of short-circuit detection and a result of loss estimation are transmitted to the controller 30.

The power device 20 includes a switching element 201 and a freewheel diode 202. In this example, the power device 20 includes a sensor 23 on an input side of the gate drive apparatus 10. The power device 20 supplies, as a sinusoidal signal, a power supply voltage to a load (not illustrated) that is connected based on the control voltage “Dr” input to a gate of the switching element 201 from the gate drive apparatus 10. The load (not illustrated) is, for example, a three-phase motor. In the present embodiment, sensor data measured by the sensor 23 installed in the power device 20 is supplied to the loss calculation circuit 12. In this example, a voltage “V_{DESAT}” of the loss calculation circuit 12 is measured by the sensor 23.

The controller 30 controls the gate drive apparatus 10. The controller 30 supplies the PWM signal to the driver circuit 11 to control operation, and supplies calculation parameters used for performing loss estimation by the loss calculation circuit 12 to adjust parameters in loss calculation. The controller 30 also receives a result of short-circuit detection and a result of loss estimation as estimation results obtained by the loss calculation circuit 12. The result of short-circuit detection is received as a short-circuit detection signal, for example. The result of loss estimation is received as an overheat detection signal, for example, or an estimated loss value is received as loss data (hereinafter, also referred to as Loss data). The controller 30 may collectively receive the short-circuit detection signal and the overheat detection signal as a Fault signal. The controller 30 may use these fed-back Loss data and Fault signal for control and the like of a duty ratio of the PWM signal in the next period, for example. The controller 30 may display these values on a display apparatus (not illustrated).

A signal transmission section between the gate drive apparatus 10 and the controller 30 is also referred to as an insulation system transmission section.

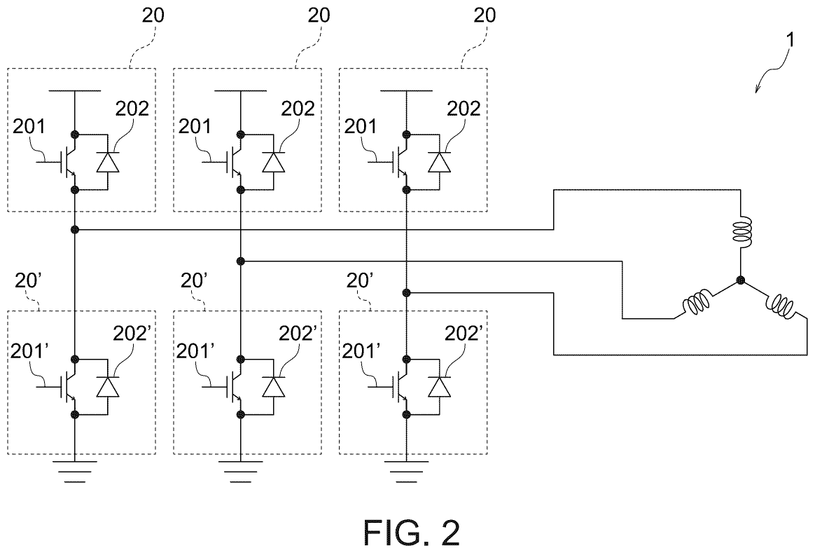

FIG. 2 is an example of a circuit diagram of an inverter 100 in the first embodiment.

In this drawing, the controller 30 and the gate drive apparatus 10 are not illustrated. As illustrated in the drawing, a plurality of the power devices 20 are used for the inverter 100 of three-phase AC, for example. Each of the power devices 20 is connected to the gate drive apparatus 10, and operates based on the PWM signal from the controller 30 as described above. For explanation, the power device 20 disposed on an opposite side of the power device 20 of a certain phase is referred to as a power device 20′, and the switching element 201 and the freewheel diode 202 included in the power device 20′ are referred to as a switching element 201′ and a freewheel diode 202′, respectively.

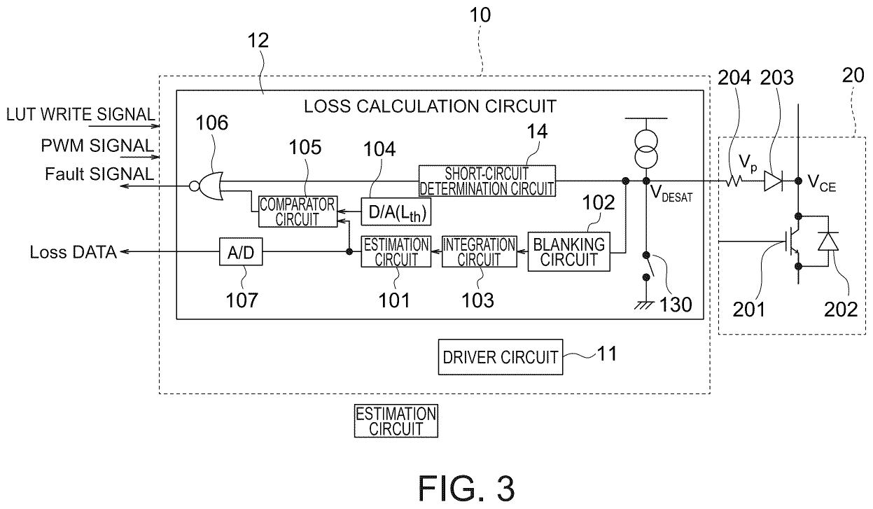

FIG. 3 is a diagram illustrating configurations of the loss calculation circuit 12 and the power device 20 in the first embodiment.

The loss calculation circuit 12 in the present embodiment includes a short-circuit determination circuit 14, an estimation circuit 101, a blanking circuit 102, a first integration circuit 103, a first D/A conversion circuit 104, a comparator circuit 105, a fault determination circuit 106, an A/D conversion circuit 107, and a switch 130. In the present embodiment, operation of the loss calculation circuit 12 is mainly described, so that description about a connection relation of the driver circuit 11 is omitted.

The loss calculation circuit 12 in the present embodiment receives, as sensor data, an input of the voltage “V_{DESAT}” as an input voltage, calculates a drain-source voltage “V_{CE}” of the switching element 201 based on the received voltage, and estimates a loss value generated in the switching element 201 thereafter. In the present embodiment, assuming that a drain-source voltage of the power device 20 is “V_{CE}” based on GND, a total voltage drop of elements corresponding to a diode 203 and a resistor 204 included in the power device 20 is assumed to be “Vₚ” (hereinafter, also simply referred to as a voltage drop “Vₚ”). In the power conversion apparatus 1, a voltage that can be measured as data of the sensor 23 in the loss calculation circuit 12 is “V_{DESAT}”. Thus, in a case of using “V_{CE}” instead of the voltage “V_{DESAT}” in performing loss calculation, the loss calculation circuit 12 may perform calculation by using the voltage “V_{DESAT}” and the voltage drop “Vₚ” by an expression (1). In calculating “V_{CE}”, a voltage calculation circuit may be disposed in the loss calculation circuit 12.

$${V}_{CE} = {V}_{DESAT} - {V}_{p} \qquad ( 1 )$$

The short-circuit determination circuit 14 performs short-circuit determination for the loss calculation circuit 12. The short-circuit determination circuit 14 performs short-circuit determination based on a value obtained by time-integrating a value of “V_{CE}” over a time “t”, for example. For example, the short-circuit determination circuit 14 performs short-circuit determination by comparing a value after the integration with a detection threshold. For example, if the value after the integration is larger than the detection threshold, the short-circuit determination circuit 14 determines that a short circuit is caused in the power device 20. If the value after the integration is equal to a value of the detection threshold, or if the value after the integration is smaller than the detection threshold, the short-circuit determination circuit 14 determines that a short circuit is not caused in the power device 20. For example, the short-circuit determination circuit 14 outputs a Low signal as a short-circuit detection signal in the former case, and outputs a High signal in the latter case.

The blanking circuit 102 performs blanking on an input value of “V_{CE}”. For example, a high voltage may be generated in the switching element 201 when the power device 20 is turned on. To prevent erroneous determination, during a period in which a value calculated as “V_{CE}” is unstable, this period is provided as a predetermined blanking time, and the blanking circuit 102 performs blanking on “V_{CE}”. During the blanking time, a function of loss calculation is disabled. The blanking time is, for example, determined based on a capacitance value of blanking capacitance included in the blanking circuit 102. During the blanking time, 0 V may be output to cause this value to be invalid in loss calculation in the loss calculation circuit 12.

The first integration circuit 103 integrates the value of “V_{CE}” over the time “t”. An integrated value calculated by the first integration circuit 103 is represented by an expression (2).

$$\begin{matrix}[ Expression 1 ] & \\ \int {V}_{CE} dt & ( 2 )\end{matrix}$$

A loss generated in the power device 20 is substantially proportional to a time-integrated value of “V_{CE}”. Thus, the loss calculation circuit 12 calculates this integrated value, and multiplies it by a predetermined proportional constant to be estimated as a loss value. Assuming that this loss is “Loss”, a relation in an expression (3) is established. If the estimated loss value “Loss” is larger than a loss threshold “Lₜₕ”, the loss calculation circuit 12 outputs a Fault signal to the controller 30. The loss calculation circuit 12 may acquire the proportional constant from an LUT signal as a calculation parameter, for example. The estimation circuit 101 multiplies the proportional constant acquired as the calculation parameter by a right side of the expression (3), that is, an integration result, to be calculated as the loss value.

$$\begin{matrix}[ Expression 2 ] & \\ Loss ∝ \int {V}_{CE} dt & ( 3 )\end{matrix}$$

The first D/A conversion circuit 104 receives an input of a Look Up Table (LUT) write signal as a calculation parameter from the controller 30, and converts the loss threshold “Lₜₕ” included in this signal from a digital value into an analog value. After digital-analog converting the loss threshold “Lₜₕ”, the first D/A conversion circuit 104 inputs the loss threshold “Lₜₕ” to the comparator circuit 105.

The comparator circuit 105 compares a value of the loss value “Loss” with a value of the loss threshold “Lₜₕ”. If the loss value “Loss” is larger than the loss threshold “Lₜₕ”, the comparator circuit 105 determines that the power device 20 is in an overheated state. If the loss value “Loss” is equal to the loss threshold “Lₜₕ”, or if the loss value “Loss” is smaller than the loss threshold “Lₜₕ”, the comparator circuit 105 determines that the power device 20 is not in the overheated state. For example, the comparator circuit 105 outputs a Low signal as the overheat detection signal in the former case, and outputs a High signal in the latter case.

The fault determination circuit 106 receives, as inputs, an output result from the short-circuit determination circuit 14 and an output result from the comparator circuit 105 to perform fault determination. If it is determined that a fault occurs, the fault determination circuit 106 outputs a Fault signal to the controller 30. In the present embodiment, the fault determination circuit 106 is constructed as a NOR circuit. When the output result from the short-circuit determination circuit 14 and the output result from the comparator circuit 105 are both Low, the NOR circuit outputs the High signal. When any of the output result from the short-circuit determination circuit 14 and the output result from the comparator circuit 105 is High, the NOR circuit outputs the Low signal. In this case, the Low signal corresponds to the Fault signal, and the controller 30 that has received the Fault signal can determine that a fault has occurred in the power device 20. In the present embodiment, the NOR circuit is used as the fault determination circuit 106, but the fault determination circuit 106 may be constructed as an OR circuit, for example. In this case, when any of the output result from the short-circuit determination circuit 14 and the output result from the comparator circuit 105 is High, the OR circuit outputs the High signal. In this case, the High signal is the Fault signal. The embodiment is not limited thereto, and the fault determination circuit 106 may be constructed by using various logic circuits.

The A/D conversion circuit 107 converts a value of “Loss” from an analog value into a digital value, and transmits it to the controller 30 as Loss data. The controller 30 that has received the Loss data performs various kinds of control such as PWM control for the next period based on the loss value “Loss” generated in the power device 20.

The switch 130 connects the loss calculation circuit 12 to GND by being opened or closed.

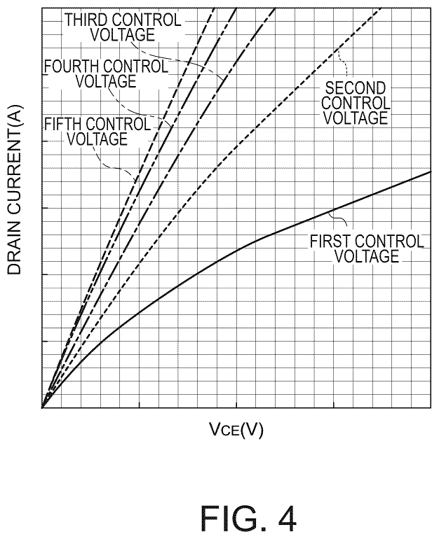

FIG. 4 is a diagram illustrating a relation between the drain-source voltage “V_{CE}” of the power device 20 and a drain current that flows at this voltage.

In this drawing, a horizontal axis indicates the drain-source voltage “V_{CE}” of the power device 20, and a vertical axis indicates a value of a drain current that flows at this voltage. In this drawing, the relation between the drain-source voltage “V_{CE}” and the drain current is indicated corresponding to each of five types of control voltages Dr from first to fifth voltages (assuming that the first control voltage<the second control voltage<the third control voltage<the fourth control voltage<the fifth control voltage is satisfied).

As illustrated in the drawing, the relation between the drain-source voltage “V_{CE}” and the drain current is a substantially proportional relation at each control voltage. There is a correlation between a current value and a loss, so that the loss value is estimated by multiplying the time-integrated value of the drain-source voltage “V_{CE}” by the proportional constant in the present embodiment. Hereinafter, the drain-source voltage “V_{CE}” is also simply referred to as a voltage “V_{CE}”.

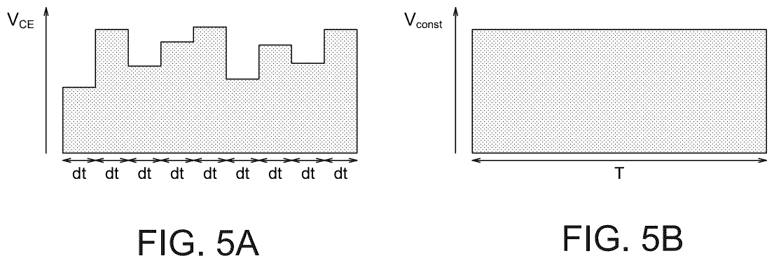

FIG. 5A and FIG. 5B are diagrams illustrating a comparative image of an estimation value of a loss in the first embodiment and an estimation value of a loss in a comparative example.

FIG. 5A illustrates the loss value “Loss” estimated by the gate drive apparatus 10 in the present embodiment, and FIG. 5B illustrates the loss value “Loss” estimated by the gate drive apparatus 10 in the comparative example. For explanation, the gate drive apparatus 10 and the power device 20 in the present embodiment are referred to as the gate drive apparatus 10 and the power device 20, and the gate drive apparatus 10 and the power device 20 in the comparative example are referred to as a gate drive apparatus 10′ and a power device 20′.

In the gate drive apparatus 10′ in the comparative example, a value obtained by multiplying a collector voltage “V_{const}” of the power device 20′ by the time “t” is estimated as the loss value.

In FIG. 5A, the gate drive apparatus 10 estimates the loss value “Loss” based on the time-integrated value of the voltage “V_{CE}” as a variable value, so that a total value of strip-shaped areas in respective “dt” sections becomes an estimation value of the loss value “Loss”. On the other hand, in FIG. 5B, a rectangular area obtained by multiplying the collector voltage “V_{const}” as a constant value by the time “t” becomes an estimation value of the loss value. The gate drive apparatus 10 in the present embodiment estimates the loss value “Loss” using the voltage “V_{CE}” as a variable value, so that accuracy is improved as compared with the comparative example.

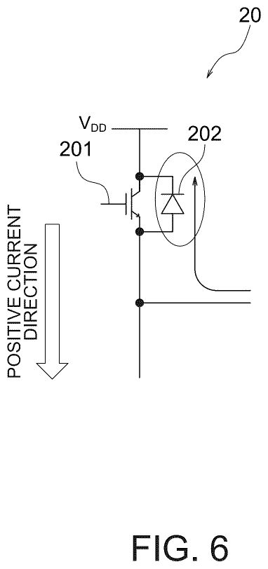

FIG. 6 is a diagram for explaining another operation of the power device 20 in the first embodiment.

With reference to this drawing, the following describes the switching element 201 and the freewheel diode 202 among constituent elements of the power device 20. The loss estimation described above is a calculation method that is used when the control voltage “Dr” is supplied to the switching element 201 and an on-voltage is produced. During an on-period, as illustrated in the drawing, a current flows in a positive current direction. On the other hand, during a period in which the switching element 201 is at an off-voltage, the current flows in a reverse direction via the freewheel diode 202, and a reverse conduction state is caused. Also in an off-period, the gate drive apparatus 10 can perform loss estimation by calculating the time-integrated value of the voltage “V_{CE}” of the switching element 201, and multiplying it by the proportional constant.

According to the present embodiment, the gate drive apparatus 10 estimates the loss value based on the time-integrated value of the voltage “V_{CE}” of the power device 20 as a variable value. Estimated loss values are transmitted to the controller 30 as Loss data, so that the controller 30 can use these values for controlling the power device 20. The gate drive apparatus 10 estimates the loss value by using the method described above, so that accuracy in loss estimation can be improved.

According to the present embodiment, the gate drive apparatus 10 performs short-circuit detection in addition to overheat detection by loss estimation. Due to this, the power device 20 can be safely used.

According to the present embodiment, the gate drive apparatus 10 can perform loss estimation not only in the on-period but also in the off-period by measuring the voltage “V_{CE}” in the reverse conduction state of the power device 20.

### Second Embodiment

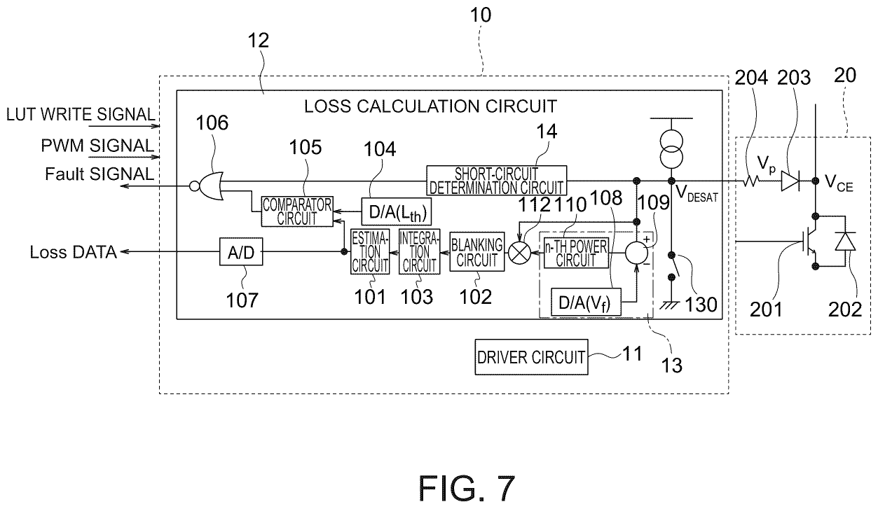

FIG. 7 is a diagram illustrating configurations of the loss calculation circuit 12 and the power device 20 in a second embodiment.

The loss calculation circuit 12 in the present embodiment includes the short-circuit determination circuit 14, the estimation circuit 101, the blanking circuit 102, the first integration circuit 103, the first D/A conversion circuit 104, the comparator circuit 105, the fault determination circuit 106, the A/D conversion circuit 107, a second D/A conversion circuit 108, a first subtraction circuit 109, an n-th power circuit 110, a first multiplication circuit 112, and the switch 130. In the present embodiment, operation of the loss calculation circuit 12 is mainly described, so that description about a connection relation of the driver circuit 11 is omitted. In the present embodiment, a circuit including the second D/A conversion circuit 108, the first subtraction circuit 109, the n-th power circuit 110, and the first multiplication circuit 112 is also referred to as a current estimation circuit 13. In the following embodiment, the circuit is constructed by using the subtraction circuit, but an addition circuit may be used instead of the subtraction circuit in accordance with a value to be input.

In the present embodiment, the loss calculation circuit 12 estimates a current value “I_{C}” flowing in the power device 20 by using the n-th power circuit 110, and performs loss estimation based on an estimation value of the current. In the present embodiment, the loss calculation circuit 12 performs estimation of the current value “I_{C}” and loss estimation by correcting the voltage “V_{CE}” with a voltage drop “V_{f}” corresponding to a work function that is generated when a diode included in the power device becomes conductive (hereinafter, also simply referred to as a voltage drop “V_{f}”). In the present embodiment, as the voltage drop “V_{f}”, a value held by the controller 30 as a calculation parameter (in this example, a constant value) is assumed to be used.

As described above, the relation between the voltage “V_{CE}” and the drain current is a substantially proportional relation. Thus, in the present embodiment, the loss calculation circuit 12 causes the n-th power (n is a real number satisfying 0=<n=<2) of a value obtained by subtracting the voltage drop “V_{f}” from the voltage “V_{CE}” to be the estimation value of the current. A value of “n” varies depending on a value of the control voltage “Dr”, so that it is a design item as a calculation parameter. For example, as the value of “n”, a value such as 0.9 or 1 may be used.

The second D/A conversion circuit 108 receives an input of the LUT write signal as a calculation parameter from the controller 30, and converts a value of the voltage drop “V_{f}” included in this signal from a digital value into an analog value. After digital-analog converting the loss threshold “Lₜₕ”, the first D/A conversion circuit 104 inputs it to the first subtraction circuit 109.

The first subtraction circuit 109 performs an arithmetic operation of subtracting the voltage drop “V_{f}” from the voltage “V_{CE}”. An arithmetic result is represented by an expression (4). The first subtraction circuit 109 inputs the arithmetic result to the n-th power circuit 110. In the present embodiment, correction is performed by using the subtraction circuit, but correction may be implemented by using an addition circuit.

$${V}_{CE} - {V}_{f} \qquad ( 4 )$$

The n-th power circuit 110 receives an input of the LUT write signal as a calculation parameter from the controller 30, raises the arithmetic result of the first subtraction circuit 109 to a power corresponding to the value of “n” included in this signal, and estimates this value as the current value “I_{C}”. The arithmetic result is represented by an expression (5). The n-th power circuit 110 inputs the arithmetic result to the first multiplication circuit 112. In estimating the loss, a proportional constant may be provided in the expression (5). In this case, the loss calculation circuit 12 may acquire the proportional constant as a calculation parameter from the LUT signal, for example.

$$\begin{matrix}[ Expression 3 ] & \\ {I}_{C} ∝ {( {V}_{CE} - {V}_{f} )}^{n} : ( n : 0 ∼ 2 ) & ( 5 )\end{matrix}$$

The first multiplication circuit 112 multiplies the estimated value of the current value “I_{C}” by the voltage “V_{CE}”. An instantaneous value of the loss value has a proportional relation with a multiplication result, so that the first multiplication circuit 112 may multiply this multiplication result by the proportional constant to be calculated as the instantaneous value of the loss. The first multiplication circuit 112 inputs the arithmetic result to the blanking circuit 102.

The blanking circuit 102 performs blanking on an input value. For example, when the power device 20 is turned on, the current value may be estimated to be a high value for the reason described above. In this way, accuracy of the value estimated as the loss value is low during a period in which the operation of the power device 20 is unstable, so that the blanking circuit 102 performs blanking on the arithmetic result obtained by the first multiplication circuit 112.

The first integration circuit 103 integrates an output result of the blanking circuit over the time “t”. The integrated value calculated by the first integration circuit 103 is represented by an expression (6). The estimation circuit 101 multiplies an integration result by a proportional constant to estimate the loss value similarly to the above description.

$$\begin{matrix}[ Expression 4 ] & \\ Loss ∝ \int {V}_{CE} \times {( {V}_{CE} - {V}_{f} )}^{n} dt & ( 6 )\end{matrix}$$

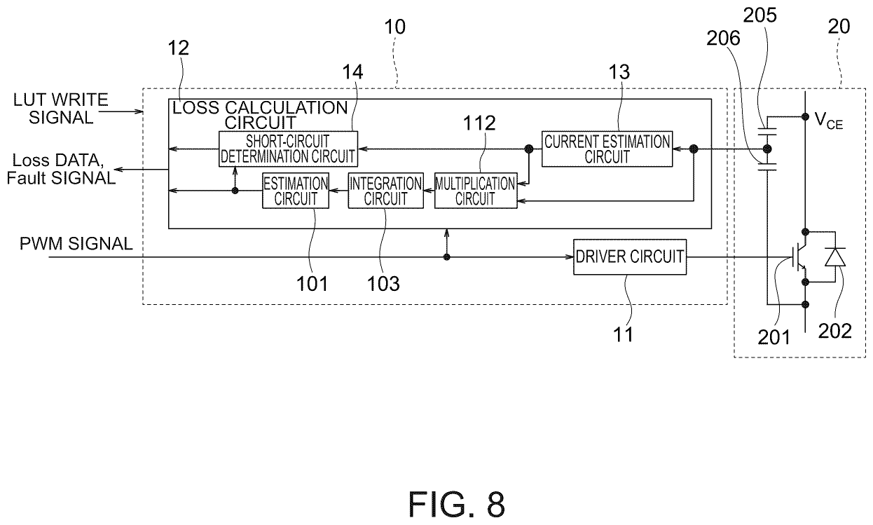

FIG. 8 is a diagram illustrating configurations of the loss calculation circuit 12 and the power device 20 in a first modification of the second embodiment.

In the present modification, from a viewpoint of pressure resistance and the like of the apparatus, the voltage “V_{CE}” of the switching element 201 is capacitively divided to be input so as to input a value of the voltage “V_{DESAT}” to the loss calculation circuit 12 as a lower value. In this modification, a first capacitor 205 and a second capacitor 206 for capacitively dividing the voltage are connected in series, and these capacitors are connected in parallel between terminals of a drain and a source of the switching element 201. The value of the voltage “V_{DESAT}” as an input voltage of the loss calculation circuit 12 is acquired from a terminal between the first capacitor 205 and the second capacitor 206. Capacitance values of the first capacitor 205 and the second capacitor 206 are design items that are determined based on pressure resistance and the like of the loss calculation circuit 12. Also in the present modification, similarly to the embodiment described above, the current estimation circuit 13 calculates the current value “I_{C}” based on the proportional relation between the voltage “V_{CE}” and the drain current.

In the present modification, a value indicating the current value “I_{C}” estimated by the current estimation circuit 13 (hereinafter, for simplifying the description, also simply referred to as the current value “I_{C}”) is input to the short-circuit determination circuit 14. The short-circuit determination circuit 14 can perform short-circuit determination by comparing, for example, the current value “I_{C}” with a threshold. In this circuit, correction of the voltage drop “Vₚ” is not required.

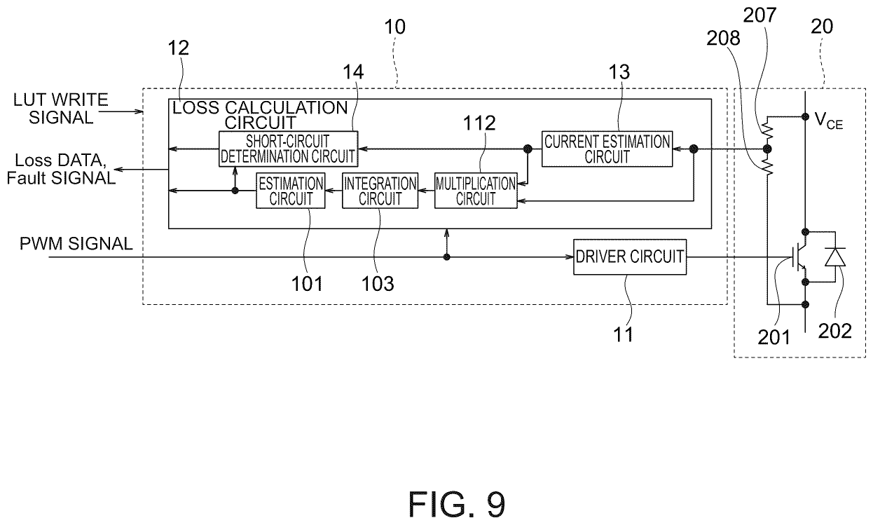

FIG. 9 is a diagram illustrating configurations of the loss calculation circuit 12 and the power device 20 in a second modification of the second embodiment.

In the present modification, to input the value of the voltage “V_{DESAT}” to the loss calculation circuit 12 as a lower value, the voltage “V_{CE}” of the switching element 201 is resistively divided to be input. In this modification, a first resistor 207 and a second resistor 208 for resistively dividing the voltage are connected in series, and these resistors are connected in parallel between terminals of the drain and the source of the switching element 201. The value of the voltage “V_{DESAT}” as an input voltage of the loss calculation circuit 12 is acquired from a terminal between the first resistor 207 and the second resistor 208. Capacitance values of the first resistor 207 and the second resistor 208 are design items that are determined based on pressure resistance and the like of the loss calculation circuit 12. Similarly to the embodiment described above, the current estimation circuit 13 calculates the current value “I_{C}” based on the proportional relation between the voltage “V_{CE}” and the drain current. In this circuit, correction of the voltage drop “Vₚ” is not required.

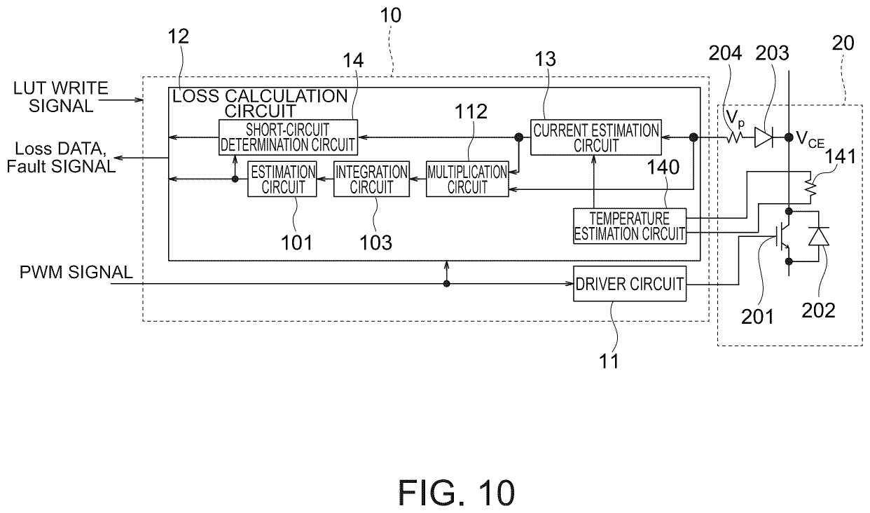

FIG. 10 is a diagram illustrating configurations of the loss calculation circuit 12 and the power device 20 in a third modification of the second embodiment.

In the present modification, in estimating the current value, the calculation parameter is changed in accordance with a temperature of the power device 20. The loss calculation circuit 12 includes a temperature estimation circuit 140 in addition to the configurations in FIG. 7. Furthermore, a thermistor 141 is provided in the power device 20.

In the present modification, the loss calculation circuit 12 includes the temperature estimation circuit 140 configured to perform temperature estimation for the power device 20. In this example, the thermistor 141 for measuring the temperature is provided on the source side of the switching element 201 for temperature estimation, and the temperature estimation circuit 140 estimates a temperature “T” of the power device 20 based on a resistance value of the thermistor 141. The temperature estimation circuit 140 inputs the estimated temperature “T” to the current estimation circuit 13.

In estimating the current value “I_{C}”, the current estimation circuit 13 corrects the value of “n” used by the n-th power circuit 110 or the value of the voltage drop “V_{f}” used by the second D/A conversion circuit 108 with the temperature “T”, for example. This correction value may be input as a calculation parameter of the LUT write signal, for example, or a correction circuit may be disposed in the current estimation circuit 13 to calculate the correction value.

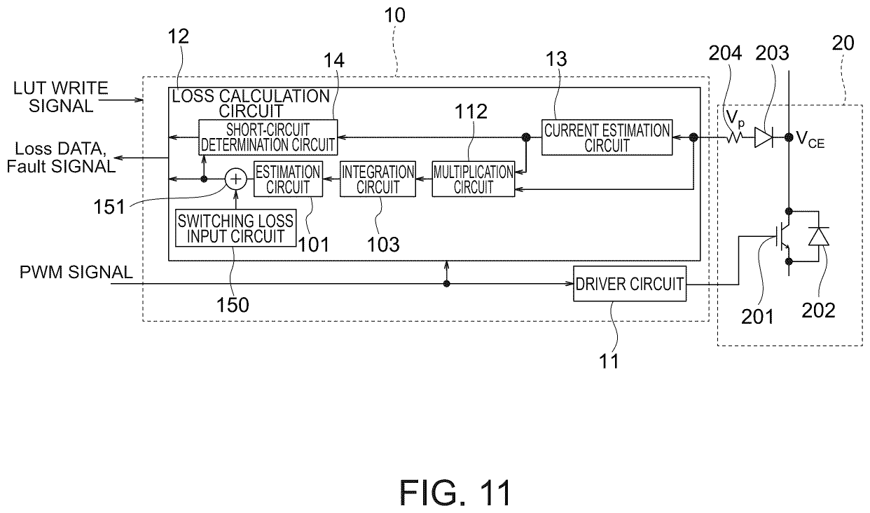

FIG. 11 is a diagram illustrating configurations of the loss calculation circuit 12 and the power device 20 in a fourth modification of the second embodiment.

In the present modification, the loss calculation circuit 12 adds a switching loss value generated by an element in the power device 20 to a loss value (mainly a conduction loss) calculated by the estimation circuit 101, and causes a total value thereof to be the estimation value of the loss value. The loss calculation circuit 12 includes a switching loss input circuit 150 and an addition circuit 151 in addition to the configurations in FIG. 7.

The switching loss input circuit 150 inputs, to the addition circuit 151, a loss value generated by switching of an element included in the power device 20. This loss value may be a constant value determined by design as a calculation parameter. A switching loss value may be, for example, a loss value generated by one time of switching of an element included in the power device 20, or may be a loss value generated in an integration time output from the first integration circuit 103.

In the present modification, the switching loss input circuit 150 also inputs this switching loss value to the short-circuit determination circuit 14. The short-circuit determination circuit 14 performs short-circuit determination by adding the value of the switching loss to the value obtained by integrating the value of “V_{CE}” over the time “t” and multiplying it by the proportional constant, and comparing the total value thereof with a threshold.

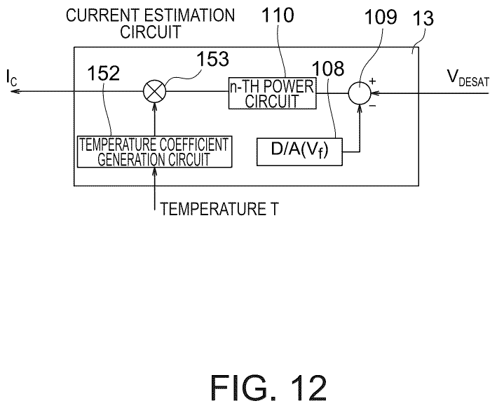

FIG. 12 is a diagram illustrating a configuration of the current estimation circuit 13 in a fifth modification of the second embodiment.

In this drawing, the configuration of the current estimation circuit 13 in the present modification is picked out and illustrated, and other configurations can be assumed to be the configurations illustrated in FIG. 7 to FIG. 11, for example.

Depending on a type of the power device 20 to be used, an order of a drain current with respect to the voltage “V_{CE}”, an offset of a work function, and a temperature dependence coefficient are different. In the present modification, the current estimation circuit 13 generates a temperature coefficient “C” in accordance with the temperature of the power device 20, and corrects the current value.

In the present modification, the current estimation circuit 13 includes the second D/A conversion circuit 108, the first subtraction circuit 109, the n-th power circuit 110, a temperature coefficient generation circuit 152, and a second multiplication circuit 153.

In the present modification, the loss calculation circuit 12 causes a value obtained by raising a value obtained by subtracting the voltage drop “V_{f}” from the voltage “V_{CE}” to the n-th power (n is a real number from 0 to 2), and multiplying it by the temperature coefficient “C” to be the estimation value of the current.

The temperature coefficient generation circuit 152 receives an input of the temperature “T”, and calculates the temperature coefficient “C” corresponding to this value. As the value of the temperature “T”, a value measured by a sensor (not illustrated) such as the thermistor 141 may be used. In a case in which the controller 30 grasps the value of the temperature “T”, the value of the temperature “T” may be included in the LUT write signal, and this signal may be input to the temperature coefficient generation circuit 152. Alternatively, the temperature coefficient “C” may be directly included in the LUT write signal to be input to the current estimation circuit 13. An input may also be received from the temperature estimation circuit 140. The temperature coefficient generation circuit 152 inputs the calculated temperature coefficient “C” to the second multiplication circuit 153.

The second multiplication circuit 153 multiplies the arithmetic result of the n-th power circuit 110 by the temperature coefficient “C”. This multiplication result is the estimation value of the current. The estimation value of the current is represented by an expression (7).

$$\begin{matrix}[ Expression 5 ] & \\ C \times {( {V}_{CE} - {V}_{f} )}^{n} & ( 7 )\end{matrix}$$

The current value “I_{C}” estimated by the current estimation circuit 13 is used for loss estimation and short-circuit determination similarly to the above description.

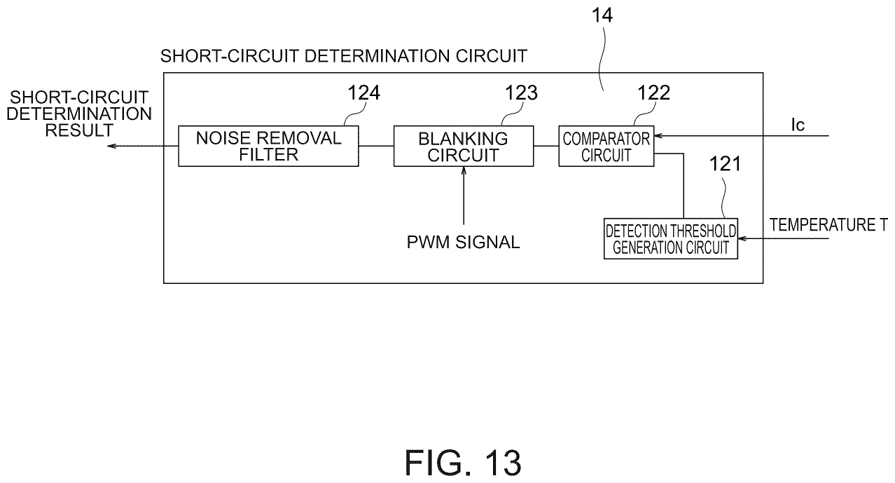

FIG. 13 is a diagram illustrating a configuration of the short-circuit determination circuit 14 in a sixth modification of the second embodiment.

In the present modification, the short-circuit determination circuit 14 includes a detection threshold generation circuit 121, a comparator circuit 122, a blanking circuit 123, and a noise removal filter 124. The short-circuit determination circuit 14 performs short-circuit determination based on the current value “I_{C}” input from the current estimation circuit 13. For example, when a large current flows in the power device 20, the short-circuit determination circuit 14 determines that a short circuit is caused. The short-circuit determination circuit 14 can adopt the loss calculation circuit 12 illustrated in FIGS. 8 to 10, for example.

The detection threshold generation circuit 121 receives an input of the value of the temperature “T”, and generates a threshold of a current with which short-circuit detection is performed. As the value of the temperature “T”, a value measured by a sensor (not illustrated) such as the thermistor 141 may be used. In a case in which the controller 30 grasps the temperature, the temperature value may be included in the LUT write signal, and this signal may be input to the detection threshold generation circuit 121. The threshold of the current may be included in the LUT write signal to be input to the short-circuit determination circuit 14.

The comparator circuit 122 receives, as inputs, the current value “I_{C}” estimated by the current estimation circuit 13 and the threshold generated by the detection threshold generation circuit 121, and performs short-circuit determination. For example, if the current value “I_{C}” is equal to or larger than the threshold, the comparator circuit 122 determines that a short circuit is caused. As a result of short-circuit determination, for example, when a short circuit is caused, the comparator circuit 122 outputs the High signal. When a short circuit is not caused, the comparator circuit 122 outputs the Low signal.

The blanking circuit 123 receives an input of the PWM signal from the controller 30, receives a result of short-circuit determination as an input from the short-circuit determination circuit 14, and performs blanking on the result of short-circuit determination in accordance with the PWM signal. For example, during a period in which an operation is unstable such as a time when the power device 20 is turned on, the result of short-circuit determination is unstable, so that blanking may be performed by the blanking circuit 123.

The noise removal filter 124 performs noise removal for a value output from the blanking circuit 123. For example, the current value “I_{C}” input to the short-circuit determination circuit 14 is an instantaneous value, so that this value is removed when an outlier is input.

The circuit configuration of the short-circuit determination circuit 14 in the present modification can be used as the short-circuit determination circuit 14 that is described above with reference to FIG. 7 in a case in which the value of “n” in the expression (5) satisfies n=1 and the value of the voltage drop “V_{f}” satisfies V_{f}=0.

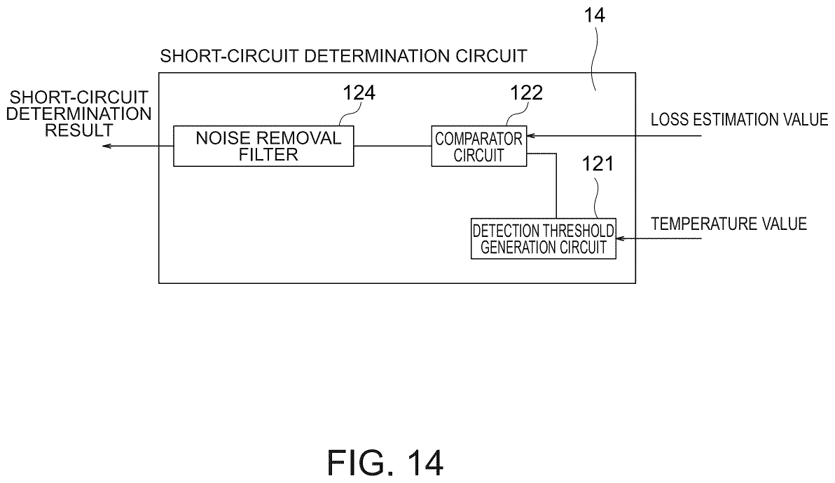

FIG. 14 is a diagram illustrating a configuration of the short-circuit determination circuit 14 in a seventh modification of the second embodiment.

In the present modification, the short-circuit determination circuit 14 includes the detection threshold generation circuit 121, the comparator circuit 122, and the noise removal filter 124. The short-circuit determination circuit 14 performs short-circuit determination based on the estimation value of the loss value input from the estimation circuit 101. For example, in a case in which a large loss is generated in the power device, the short-circuit determination circuit 14 determines that a short circuit is caused. The short-circuit determination circuit 14 can be adopted for any of the configurations of the loss calculation circuit 12 described above so long as the short-circuit determination circuit 14 has a configuration of receiving a branched input from the estimation circuit 101.

The detection threshold generation circuit 121 receives an input of the temperature “T”, and generates a threshold of an estimation value of a loss with which short-circuit detection is performed. As the value of the temperature “T”, a value measured by a sensor (not illustrated) such as the thermistor 141 may be used. In a case in which the controller 30 grasps the temperature, the value of the temperature “T” may be included in the LUT write signal, and this signal may be input to the temperature coefficient generation circuit 152. The temperature coefficient generation circuit 152 may convert the threshold determined based on the temperature “T” from a digital value into an analog value.

The comparator circuit 122 receives, as inputs, the loss value estimated by the estimation circuit 101 and the threshold generated by the detection threshold generation circuit 121, and performs short-circuit determination. For example, if the estimation value of the loss value is equal to or larger than the threshold, the comparator circuit 122 determines that a short circuit is caused. As a result of short-circuit determination, for example, when a short circuit is caused, the comparator circuit 122 outputs the High signal. When a short circuit is not caused, the comparator circuit 122 outputs the Low signal.

The noise removal filter 124 performs noise removal for a value output from the comparator circuit 122.

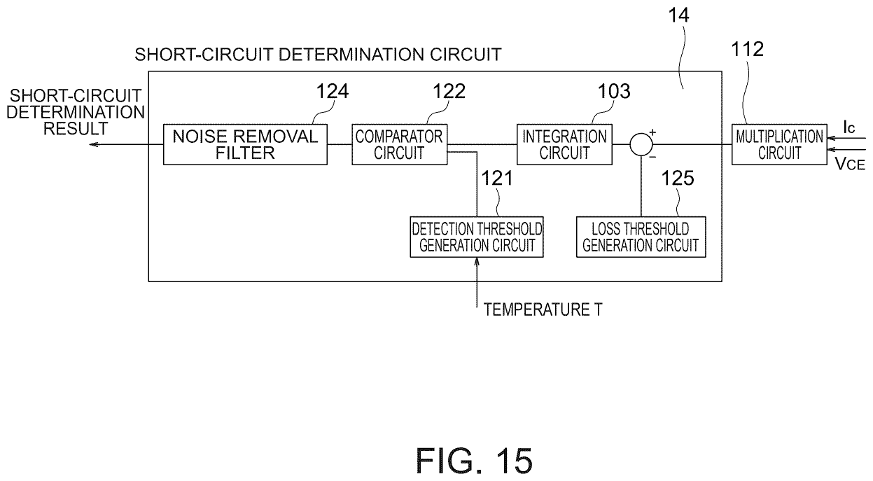

FIG. 15 is a diagram illustrating a configuration of the short-circuit determination circuit 14 in an eighth modification of the second embodiment.

In the present modification, the short-circuit determination circuit 14 includes a loss threshold generation circuit 125, the first integration circuit 103, the detection threshold generation circuit 121, the comparator circuit 122, and the noise removal filter 124. The short-circuit determination circuit 14 performs short-circuit determination based on a multiplication result of the voltage “V_{CE}” and the value of the current value “I_{C}” input from the first multiplication circuit 112. When the loss is large, a heating value is also large, so that the short-circuit determination circuit 14 compares a time-integrated value with a detection threshold that is generated based on the temperature “T” to perform short-circuit determination. For example, the short-circuit determination circuit 14 determines that a short circuit is caused when the heating value of the power device 20 is large, that is, when the temperature is high. The short-circuit determination circuit 14 can be adopted for any of the configurations of the loss calculation circuit 12 described above so long as the short-circuit determination circuit 14 has a configuration of receiving the multiplication result as an input from the first multiplication circuit 112.

The loss threshold generation circuit 125 generates a loss threshold “Lₜₕ” with which loss detection is performed. In generating the loss threshold “Lₜₕ”, the loss threshold generation circuit 125 receives an input of the LUT write signal as a calculation parameter from the controller 30, for example, and converts a value of the loss threshold “Lₜₕ” included in this signal from a digital value into an analog value.

The first integration circuit 103 time-integrates a multiplication result of the value of the current value “I_{C}” and the voltage “V_{CE}”. In a case in which the multiplication result of the value of the current value “I_{C}” and the voltage “V_{CE}” is smaller than the loss threshold “Lₜₕ”, the first integration circuit 103 does not necessarily use this multiplication result for integration.

The detection threshold generation circuit 121 receives an input of the value of the temperature “T”, and generates a threshold of an integrated value with which short-circuit detection is performed. As the value of the temperature “T”, a value measured by a sensor (not illustrated) such as the thermistor 141 may be used. In a case in which the controller 30 grasps the temperature, the temperature value may be included in the LUT write signal, and this signal may be input to the detection threshold generation circuit 121.

The comparator circuit 122 receives, as inputs, the integrated value calculated by the first integration circuit 103 and the threshold of the integrated value, and performs short-circuit determination. For example, if the integrated value is equal to or larger than the threshold, the comparator circuit 122 determines that a short circuit is caused. As a result of short-circuit determination, for example, when a short circuit is caused, the comparator circuit 122 outputs the High signal. When a short circuit is not caused, the comparator circuit 122 outputs the Low signal.

The noise removal filter 124 performs noise removal for a value output from the comparator circuit 122.

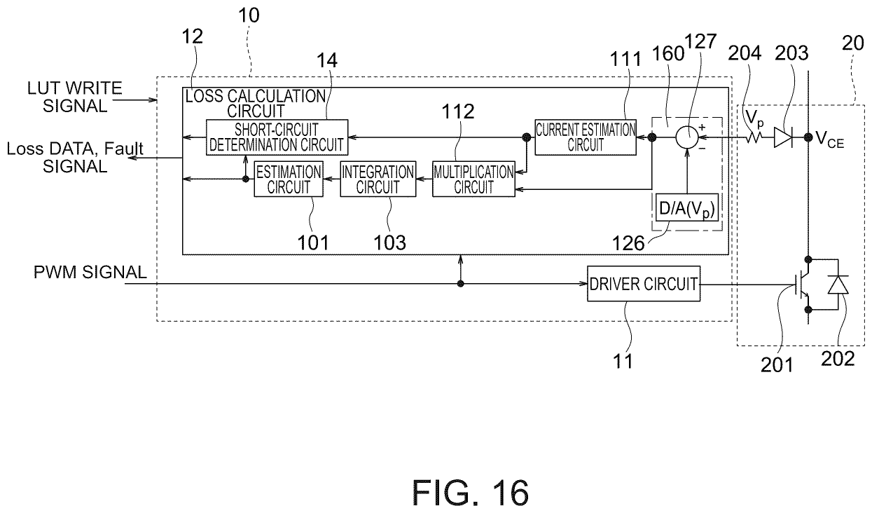

FIG. 16 is a diagram illustrating configurations of the loss calculation circuit 12 and the power device 20 in a ninth modification of the second embodiment.

In the present modification, the loss calculation circuit 12 includes a front-end device 160 that corrects the voltage “V_{DESAT}” with the voltage drop “Vₚ” as an input voltage to be input to the current estimation circuit 13. The front-end device 160 includes a third D/A conversion circuit 126 and a second subtraction circuit 127.

The third D/A conversion circuit 126 receives an input of the LUT write signal as a calculation parameter from the controller 30, and converts the value of the voltage drop “Vₚ” included in this signal from a digital value into an analog value. After digital-analog converting the value of the voltage drop “Vₚ”, the third D/A conversion circuit 126 inputs the value to the second subtraction circuit 127.

The second subtraction circuit 127 performs an arithmetic operation of subtracting the voltage drop “Vₚ” from the voltage “V_{CE}”. The first subtraction circuit 109 inputs the arithmetic result to the current estimation circuit 13. The current estimation circuit 13 may estimate the current value by further using the voltage drop “V_{f}” for this voltage value, or may estimate the current value “I_{C}” without subtracting this value. The current is estimated by using the method described above. In the present modification, correction is performed by using the subtraction circuit, but correction may be implemented by an addition circuit.

According to the present embodiment and modifications, the loss calculation circuit 12 estimates the current value “I_{C}” of the drain current flowing through the power device 20 based on the voltage “V_{CE}”. Due to this, the loss can be estimated without using a current sensor, so that an area of the power device 20 can be reduced, or production cost can be reduced. The estimated loss values are transmitted to the controller 30 as the Loss data, so that the controller 30 can use these values for controlling the power device 20.

According to the third modification of the present embodiment, the loss calculation circuit 12 estimates the temperature “T” of the power device 20, and corrects the value of the voltage drop “V_{f}” with the temperature “T” in estimating the current value “I_{C}”. Due to this, the loss calculation circuit 12 can perform loss estimation and short-circuit detection with high accuracy against temperature variation of the power device 20.

According to the fourth modification of the present embodiment, the loss calculation circuit 12 adds the switching loss value generated by an element in the power device 20 to the loss value (mainly a conduction loss) calculated by the estimation circuit 101, and estimates a total value thereof as a loss. By correcting the integrated value with a switch loss, the loss calculation circuit 12 can improve accuracy of loss estimation and short-circuit detection.

According to the fifth modification of the present embodiment, the loss calculation circuit 12 corrects the current value “I_{C}” by using the temperature coefficient “C” generated by the temperature coefficient generation circuit 152. The loss calculation circuit 12 can improve accuracy of loss estimation and short-circuit detection by correcting the current value “I_{C}” with the temperature coefficient.

According to the sixth modification of the present embodiment, the loss calculation circuit 12 performs short-circuit determination based on the current value “I_{C}” and the value of the temperature “T”. Due to this, the loss calculation circuit 12 can protect the power device 20 based on the current value “I_{C}” and the value of the temperature “T” instead of the voltage value.

According to the seventh modification of the present embodiment, the loss calculation circuit 12 performs short-circuit determination based on the estimation value of the loss value input from the first integration circuit 103. Due to this, the loss calculation circuit 12 can protect the power device 20 based on the estimation value of the loss value instead of the current value.

According to the eighth modification of the present embodiment, the loss calculation circuit 12 compares the heating value with the detection threshold that is generated based on the temperature “T” to perform short-circuit determination. Due to this, the loss calculation circuit 12 can estimate the temperature of the power device 20 with higher accuracy than that in the seventh modification, and can further improve accuracy of loss estimation and short-circuit detection.

According to the ninth modification of the present embodiment, the loss calculation circuit 12 includes the front-end device 160 that subtracts the voltage drop “Vₚ” from the voltage “V_{CE}”. By correcting the voltage drop “Vₚ”, the loss calculation circuit 12 can improve accuracy of the arithmetic operation.

### Third Embodiment

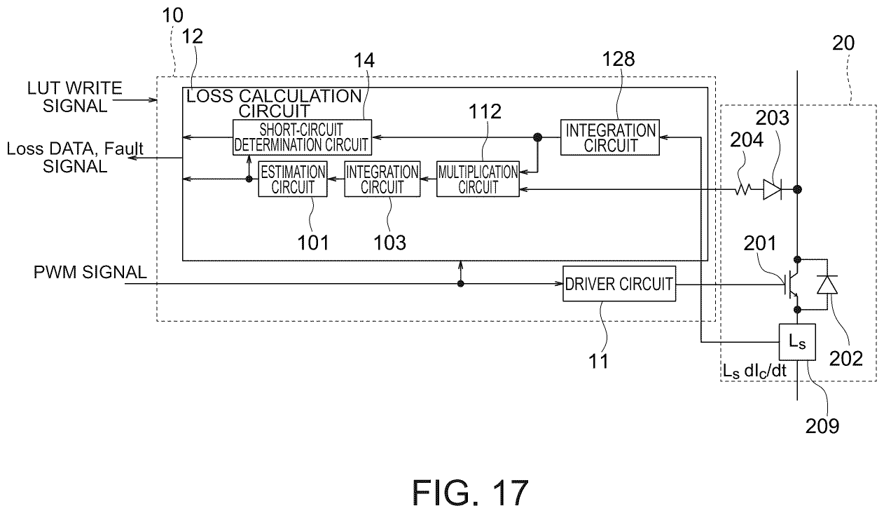

FIG. 17 is a diagram illustrating configurations of the loss calculation circuit 12 and the power device 20 in a third embodiment.

In the present embodiment, the power device 20 includes an inductance 209. The loss calculation circuit 12 receives, as an input, a value of an inter-terminal voltage of the inductance 209 as sensor data to be time-integrated, and estimates this value as the current value “I_{C}”. For explanation, the value of the inductance 209 is assumed to be “Lₛ”. The inductance 209 may be a parasite inductance, or an element inductance.

The loss calculation circuit 12 includes the first multiplication circuit 112, the first integration circuit 103, the short-circuit determination circuit 14, and a second integration circuit 128.

The second integration circuit 128 receives, as LₛdI_{c}/dt, an input of a value of the inter-terminal voltage of the inductance 209 in the power device 20. The second integration circuit 128 time-integrates the inter-terminal voltage LₛdI_{c}/dt that has been input, and calculates the current value “I_{C}”. The second integration circuit 128 inputs a result of the arithmetic operation to the short-circuit determination circuit 14 and the first multiplication circuit 112.

The first integration circuit 103 integrates the multiplication result obtained by the first multiplication circuit 112 over the time “t”. The estimation circuit 101 multiplies an integration result by a proportional constant to calculate the estimation value of the loss value. The short-circuit determination circuit 14 performs short-circuit determination by comparing the current value “I_{C}” with a threshold, for example, using the same method as described above.

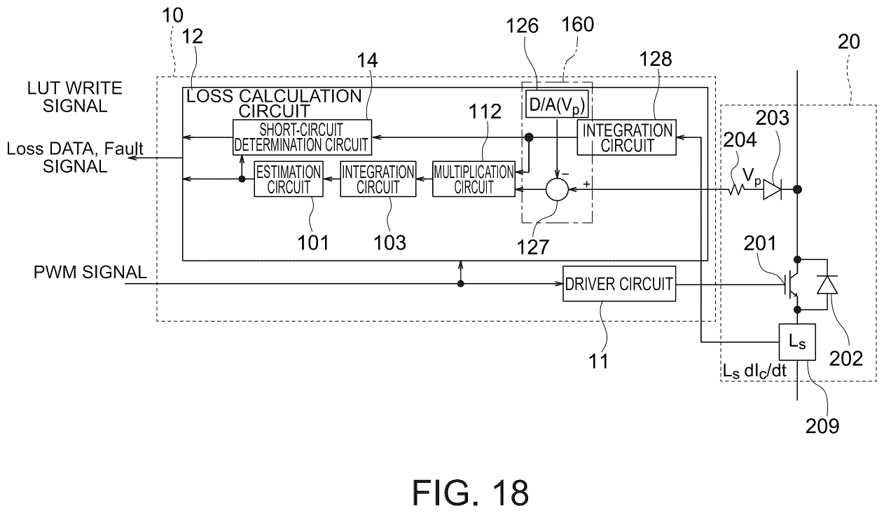

FIG. 18 is a diagram illustrating configurations of the loss calculation circuit 12 and the power device 20 in a modification of the third embodiment.

In the present modification, the loss calculation circuit 12 includes the front-end device 160 that corrects the voltage “V_{CE}” with the voltage drop “Vₚ” as an input voltage to be input to the current estimation circuit 13. The front-end device 160 includes the third D/A conversion circuit 126 and the second subtraction circuit 127.

The first multiplication circuit 112 multiplies the value of the current value “I_{C}” by the voltage “V_{CE}”.

The third D/A conversion circuit 126 receives an input of the LUT write signal as a calculation parameter from the controller 30, and converts the value of the voltage drop “Vₚ” included in this signal from a digital value into an analog value. After digital-analog converting the value of the voltage drop “Vₚ”, the third D/A conversion circuit 126 inputs the value to the second subtraction circuit 127.

The second subtraction circuit 127 performs an arithmetic operation of subtracting the voltage drop “Vₚ” from the voltage “V_{CE}”. The first subtraction circuit 109 inputs the arithmetic result to the current estimation circuit 13. The current estimation circuit 13 may further use the voltage drop “V_{f}” for this voltage value to estimate the current value, or may estimate the current value “I_{C}” without subtracting this value. Estimation of the current is performed by using the method described above. In the present modification, correction is performed by using the subtraction circuit, but correction may be implemented by an addition circuit.

The first multiplication circuit 112 receives inputs of an arithmetic result of the second subtraction circuit 127 and an arithmetic result of the second integration circuit 128 to perform multiplication. A multiplication result is input to the first integration circuit 103 and time-integrated. Thereafter, the estimation circuit 101 multiplies the multiplication result by a proportional constant to calculate the estimation value of the loss.

According to the present embodiment and the modification, the loss calculation circuit 12 can estimate the loss value with a simple structure without providing a current sensor in the power device 20, so that an area of the power device 20 can be reduced, or production cost can be reduced.

According to the modification of the present embodiment, the loss calculation circuit 12 includes the front-end device 160 that subtracts the voltage drop “Vₚ” from the voltage “V_{CE}”. The loss calculation circuit 12 corrects the voltage drop “Vₚ” in multiplication, so that accuracy of the arithmetic operation can be improved.

### Fourth Embodiment

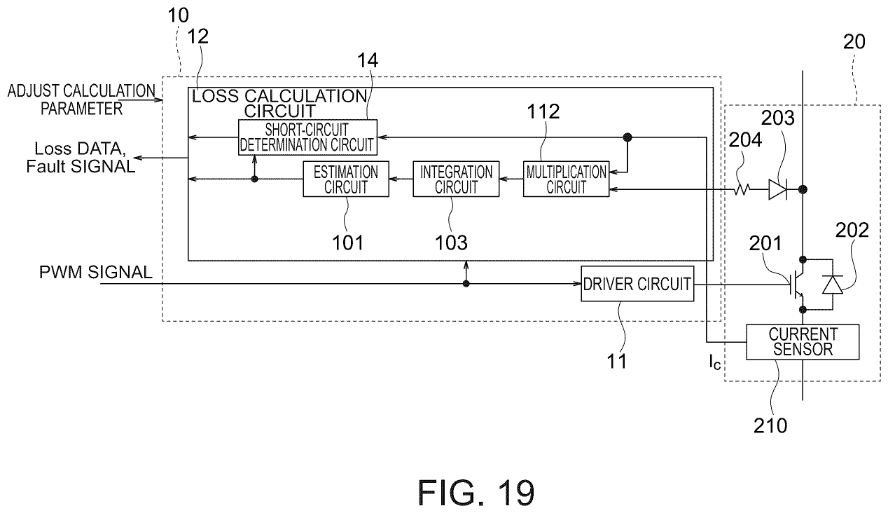

FIG. 19 is a diagram illustrating configurations of the loss calculation circuit 12 and the power device 20 in a fourth embodiment.

In the present embodiment, the power device 20 includes a current sensor 210. The loss calculation circuit 12 receives an input of the current value “I_{C}” measured by the current sensor 210.

The first multiplication circuit 112 multiplies the current value “I_{C}” input from the power device 20 as sensor data by the voltage “V_{CE}”. The first integration circuit 103 integrates a multiplication result over the time “t”. The estimation circuit 101 calculates the estimation value of the loss value using the same method as described above. The short-circuit determination circuit 14 receives an input of the current value “I_{C}” measured by the current sensor, and performs short-circuit determination by comparing the current value “I_{C}” with the threshold, for example, using the same method as described above.

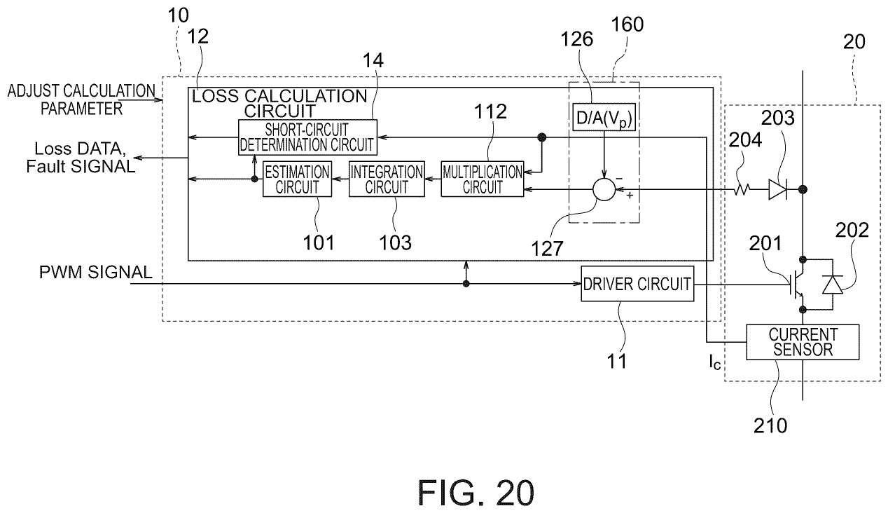

FIG. 20 is a diagram illustrating configurations of the loss calculation circuit 12 and the power device 20 in a modification of the fourth embodiment.

In the present modification, the loss calculation circuit 12 includes the front-end device 160 that corrects the voltage “V_{CE}” with the voltage drop “Vₚ” as an input voltage to be input to the current estimation circuit 13. The front-end device 160 includes the third D/A conversion circuit 126 and the second subtraction circuit 127.

The second subtraction circuit 127 performs an arithmetic operation of subtracting the voltage drop “Vₚ” from the voltage “V_{CE}”. The first subtraction circuit 109 inputs the arithmetic result to the current estimation circuit 13. The current estimation circuit 13 may further use the voltage drop “V” for this voltage value to estimate the current value, or may estimate the current value “I_{C}” without subtracting this value. Estimation of the current is performed by using the method described above. In the present modification, correction is performed by using the subtraction circuit, but correction may be implemented by an addition circuit.

The first multiplication circuit 112 receives inputs of an arithmetic result of the second subtraction circuit 127 and the current value “I_{C}” from the current sensor 210 to calculate the estimation value of the loss value.

According to the present embodiment and the modification, the loss calculation circuit 12 estimates the loss value using the sensor data of the current sensor 210 included in the power device 20. Due to this, the loss calculation circuit 12 can further improve accuracy of loss estimation and short-circuit detection.

According to the present embodiment and the modification, even in a case in which a plurality of the switching elements 201 are disposed in the circuit similarly to the inverter 100, and a plurality of states such as a turn-on state, on state, and off state coexist among the plurality of switching elements 201, the loss calculation circuit 12 can estimate the loss with high accuracy by measuring the current at each measurement point.

According to the modification of the present embodiment, the loss calculation circuit 12 includes the front-end device 160 that subtracts the voltage drop “Vₚ” from the voltage “V_{CE}”. The loss calculation circuit 12 can improve accuracy of the arithmetic operation by correcting the voltage drop “Vₚ” generated by the diode 203 and the resistor 204.

The several embodiments have been described above, but these embodiments are merely examples, and do not intend to limit the scope of the invention. The novel gate drive apparatus 10 described in this specification can be implemented in various other forms. The forms of the gate drive apparatus 10 described in the present specification can be variously omitted, replaced, or modified without departing from the gist of the invention. The attached CLAIMS and equivalents thereof intend to encompass such forms or modifications included in the scope and the gist of the invention.

### SUPPLEMENT

For example, the present embodiments and the modifications thereof may have configurations as described below.

(1)

A gate drive apparatus including:
a loss calculation circuit configured to estimate a loss value of a power device by using voltage values at a plurality of time points of the power device, wherein
the loss calculation circuit includes:
   an integration circuit configured to perform time integration based on the voltage values at the plurality of time points; and
   an estimation circuit configured to estimate the loss value of the power device based on a result of the time integration.
      (2)

The gate drive apparatus according to (1), further including:
a driver circuit configured to operate in accordance with an input control signal to drive the power device.
   (3)

The gate drive apparatus according to (1) and (2), wherein
the loss calculation circuit further includes a blanking circuit configured to perform blanking on the voltage value of the power device at a predetermined blanking time among the plurality of time points, and
the integration circuit performs time integration by using the voltage value after the blanking time has elapsed.
   (4)

The gate drive apparatus according to (1) to (3), wherein the loss calculation circuit further receives, as an input, at least one of a value of a voltage drop of an element included in the power device, a value of a switching loss, a temperature of the power device, a temperature coefficient for correcting a current value in accordance with the temperature of the power device, and a detection threshold of the loss value, and estimates the loss value.

(5)

The gate drive apparatus according to (1) to (4), wherein
the loss calculation circuit further includes a current estimation circuit configured to estimate a current value flowing in the power device, and
the current estimation circuit raises a value obtained by correcting the voltage value with a voltage corresponding to a voltage drop caused by a work function of an element included in the power device to the n-th power (n is a real number satisfying 0=<n=<2), and estimates the current value.
   (6)

The gate drive apparatus according to (1) to (4), wherein
the loss calculation circuit further includes an n-th power circuit configured to raise an input value to the n-th power (n is a real number satisfying 0=<n=<2) to be output,
the n-th power circuit raises a value obtained by correcting the voltage value with a voltage corresponding to a voltage drop caused by a work function of an element included in the power device to the n-th power to be output, and
the integration circuit performs time integration by using the voltage values at the plurality of time points and an output value of the n-th power circuit.
   (7)

The gate drive apparatus according to (1) to (5), wherein
the loss calculation circuit further includes a temperature estimation circuit configured to estimate a temperature of the power device, and
the loss calculation circuit changes a calculation parameter of any one of the value of “n” and a voltage corresponding to a voltage drop caused by a work function of the element included in the power device based on an estimated temperature.
   (8)

The gate drive apparatus according to (1) to (7), wherein
the loss calculation circuit further includes a switching loss input circuit configured to input a value of a switching loss generated by an element included in the power device, and
the loss calculation circuit adds the value of the switching loss to an output value from the estimation circuit to be estimated as the loss value.
   (9)

The gate drive apparatus according to (5) to (8), wherein
the current estimation circuit further includes a temperature coefficient generation circuit configured to calculate a temperature coefficient corresponding to a temperature of the power device, and
the current estimation circuit raises, to the n-th power, a value obtained by subtracting a predetermined voltage from a drain-source voltage of a switching element of the power device calculated based on the voltage value, and multiplies this value by the temperature coefficient to estimate the current value.
   (10)

The gate drive apparatus according to (5) to (9), wherein
the loss calculation circuit further includes a short-circuit determination circuit configured to perform short-circuit determination, and
the short-circuit determination circuit performs short-circuit determination by using the current value and a temperature of the power device.
   (11)

The gate drive apparatus according to (1) to (10), wherein
the loss calculation circuit further includes a short-circuit determination circuit configured to perform short-circuit determination, and
the short-circuit determination circuit performs short-circuit determination by using the loss value and a temperature of the power device.
   (12)

The gate drive apparatus according to (5) to (10), wherein
the loss calculation circuit further includes a short-circuit determination circuit configured to perform short-circuit determination, and
the short-circuit determination circuit performs short-circuit determination by using a multiplication result of the voltage value and the current value, and a temperature of the power device.
   (13)

The gate drive apparatus according to (1) to (4), wherein
the loss calculation circuit further includes:
   a current estimation circuit configured to estimate a current value flowing in the power device; and
   a front-end device configured to correct the voltage value with a voltage corresponding to a voltage drop of an element included in the power device, and
the loss calculation circuit estimates the loss value by using the current value and a value obtained by correcting the voltage value with a voltage corresponding to a voltage drop of an element included in the power device.
   (14)

The gate drive apparatus according to (1) to (4), wherein
the loss calculation circuit further includes an integration circuit configured to estimate a current value flowing in the power device by using an inter-terminal voltage of an inductance in the power device, and
the integration circuit time-integrates the inter-terminal voltage and estimates the current value.
   (15)

The gate drive apparatus according to (14), wherein
the loss calculation circuit further includes a front-end device configured to correct the voltage value with a voltage corresponding to a voltage drop of an element included in the power device, and
the loss calculation circuit estimates the loss value by using the current value and a value obtained by correcting the voltage value with the voltage corresponding to a voltage drop of an element included in the power device.
   (16)

The gate drive apparatus according to (1) to (4), wherein the loss calculation circuit receives a current value flowing in the power device as an input, and estimates the loss value based on the current value and the voltage value.

(17)

The gate drive apparatus according to (16), wherein
the loss calculation circuit further includes a front-end device configured to correct the voltage value with a voltage corresponding to a voltage drop of an element included in the power device, and
the loss calculation circuit estimates the loss value by using the current value and a value obtained by correcting the voltage value with a voltage corresponding to a voltage drop of an element included in the power device.
   (18)

The gate drive apparatus according to (1) to (4), wherein the loss calculation circuit transmits a value of the loss value to a controller.

(19)

A power conversion apparatus including a gate drive apparatus, wherein
the gate drive apparatus includes:
   a loss calculation circuit configured to estimate a loss value of a power device by using voltage values at a plurality of time points of the power device, and
the loss calculation circuit includes:
   an integration circuit configured to perform time integration based on the voltage values at the plurality of time points; and
   an estimation circuit configured to estimate a loss value of the power device based on a result of the time integration.
      (20)

An inverter including a plurality of gate drive apparatuses, wherein
the plurality of gate drive apparatuses include:
   a loss calculation circuit configured to estimate a loss value of a power device by using voltage values at a plurality of time points of the power device, and
the loss calculation circuit includes:
   an integration circuit configured to perform time integration based on the voltage values at the plurality of time points; and
   an estimation circuit configured to estimate a loss value of the power device based on a result of the time integration.

1. A gate drive apparatus comprising:
a loss calculation circuit configured to estimate a loss value of a power device by using voltage values at a plurality of time points of the power device, wherein
the loss calculation circuit includes:
an integration circuit configured to perform time integration based on the voltage values at the plurality of time points; and
an estimation circuit configured to estimate the loss value of the power device based on a result of the time integration.

2. The gate drive apparatus according to claim 1, further comprising:
a driver circuit configured to operate in accordance with an input control signal to drive the power device.

3. The gate drive apparatus according to claim 1, wherein
the loss calculation circuit further includes a blanking circuit configured to perform blanking on the voltage value of the power device at a predetermined blanking time among the plurality of time points, and
the integration circuit performs time integration by using the voltage value after the blanking time has elapsed.

4. The gate drive apparatus according to claim 1, wherein the loss calculation circuit further receives, as an input, at least one of a value of a voltage drop of an element included in the power device, a value of a switching loss, a temperature of the power device, a temperature coefficient for correcting a current value in accordance with the temperature of the power device, and a detection threshold of the loss value, and estimates the loss value.

5. The gate drive apparatus according to claim 1, wherein
the loss calculation circuit further includes a current estimation circuit configured to estimate a current value flowing in the power device, and
the current estimation circuit raises a value obtained by correcting the voltage value with a voltage corresponding to a voltage drop caused by a work function of an element included in the power device to the n-th power (n is a real number satisfying 0=<n=<2), and estimates the current value.

6. The gate drive apparatus according to claim 1, wherein
the loss calculation circuit further includes an n-th power circuit configured to raise an input value to the n-th power (n is a real number satisfying 0=<n=<2) to be output,
the n-th power circuit raises a value obtained by correcting the voltage value with a voltage corresponding to a voltage drop caused by a work function of an element included in the power device to the n-th power to be output, and
the integration circuit performs time integration by using the voltage values at the plurality of time points and an output value of the n-th power circuit.

7. The gate drive apparatus according to claim 5, wherein
the loss calculation circuit further includes a temperature estimation circuit configured to estimate a temperature of the power device, and
the loss calculation circuit changes at least one of the value of “n” and a voltage corresponding to a voltage drop caused by a work function of the element included in the power device based on an estimated temperature.

8. The gate drive apparatus according to claim 5, wherein
the loss calculation circuit further includes a switching loss input circuit configured to input a value of a switching loss generated by an element included in the power device, and
the loss calculation circuit adds the value of the switching loss to an output value from the estimation circuit to be estimated as the loss value.

9. The gate drive apparatus according to claim 5, wherein
the current estimation circuit further includes a temperature coefficient generation circuit configured to calculate a temperature coefficient corresponding to a temperature of the power device, and
the current estimation circuit raises, to the n-th power, a value obtained by subtracting a predetermined voltage from a drain-source voltage of a switching element of the power device calculated based on the voltage value, and multiplies this value by the temperature coefficient to estimate the current value.

10. The gate drive apparatus according to claim 5, wherein
the loss calculation circuit further includes a short-circuit determination circuit configured to perform short-circuit determination, and
the short-circuit determination circuit performs short-circuit determination by using the current value and a temperature of the power device.

11. The gate drive apparatus according to claim 1, wherein
the loss calculation circuit further includes a short-circuit determination circuit configured to perform short-circuit determination, and
the short-circuit determination circuit performs short-circuit determination by using the loss value and a temperature of the power device.

12. The gate drive apparatus according to claim 5, wherein
the loss calculation circuit further includes a short-circuit determination circuit configured to perform short-circuit determination, and
the short-circuit determination circuit performs short-circuit determination by using a multiplication result of the voltage value and the current value, and a temperature of the power device.

13. The gate drive apparatus according to claim 1, wherein
the loss calculation circuit further includes:
a current estimation circuit configured to estimate a current value flowing in the power device; and
a front-end device configured to correct the voltage value with a voltage corresponding to a voltage drop of an element included in the power device, and
the loss calculation circuit estimates the loss value by using the current value and a value obtained by correcting the voltage value with a voltage corresponding to a voltage drop of an element included in the power device.

14. The gate drive apparatus according to claim 1, wherein
the loss calculation circuit further includes an integration circuit configured to estimate a current value flowing in the power device by using an inter-terminal voltage of an inductance in the power device, and
the integration circuit time-integrates the inter-terminal voltage and estimates the current value.

15. The gate drive apparatus according to claim 14, wherein
the loss calculation circuit further includes a front-end device configured to correct the voltage value with a voltage corresponding to a voltage drop of an element included in the power device, and
the loss calculation circuit estimates the loss value by using the current value and a value obtained by correcting the voltage value with the voltage corresponding to a voltage drop of an element included in the power device.

16. The gate drive apparatus according to claim 1, wherein the loss calculation circuit estimates the loss value based on a current value flowing in the power device and the voltage value.

17. The gate drive apparatus according to claim 16, wherein
the loss calculation circuit further includes a front-end device configured to correct the voltage value with a voltage corresponding to a voltage drop of an element included in the power device, and
the loss calculation circuit estimates the loss value by using the current value and a value obtained by correcting the voltage value with a voltage corresponding to a voltage drop of an element included in the power device.

18. The gate drive apparatus according to claim 1, wherein the loss calculation circuit transmits a value of the loss value to a controller.

19. A power conversion apparatus comprising a gate drive apparatus, wherein
the gate drive apparatus includes:
a loss calculation circuit configured to estimate a loss value of a power device by using voltage values at a plurality of time points of the power device, and
the loss calculation circuit includes:
an integration circuit configured to perform time integration based on the voltage values at the plurality of time points; and
an estimation circuit configured to estimate a loss value of the power device based on a result of the time integration.

20. An inverter comprising a plurality of gate drive apparatuses, wherein
the plurality of gate drive apparatuses include:
a loss calculation circuit configured to estimate a loss value of a power device by using voltage values at a plurality of time points of the power device, and
the loss calculation circuit includes:
an integration circuit configured to perform time integration based on the voltage values at the plurality of time points; and
an estimation circuit configured to estimate a loss value of the power device based on a result of the time integration.
